(19) United States
(12) Patent Application Publication
(10) Pub. No.: US 2021/0193650 A1
(43) Pub. Date: Jun. 24, 2021

(54) DISPLAY PANEL AND DISPLAY DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Yongda MA, Beijing (CN); Xinyin WU, Beijing (CN); Jianbo XIAN, Beijing (CN)

(21) Appl. No.: 17/128,356

(22) Filed: Dec. 21, 2020

(30) Foreign Application Priority Data
Dec. 20, 2019 (CN) 201922313769.X

(51) Int. Cl. H01L 27/02; H01L 27/12

(52) U.S. Cl. CPC H01L 27/0292; H01L 27/0296; H01L 27/124; H01L 27/0266

(57) ABSTRACT

A display panel includes a plurality of signal lines, at least one conductive pattern, and a plurality of first switch units. Each of at least part of the signal lines is electrically connected to the at least one conductive pattern through at least one first switch unit. Each first switch unit is connected between a corresponding signal line and a corresponding conductive pattern, and includes a control portion and an electrostatic buffer portion. The control portion is electrically connected between the corresponding signal line and the electrostatic buffer portion, and is configured to close a line between the signal line and the electrostatic buffer portion in response to an electrostatic voltage of electrostatic charges. The electrostatic buffer portion includes a connecting sub-portion and an extension sub-portion. The control portion, the corresponding conductive pattern and the extension sub-portion are electrically connected together through the connecting sub-portion.

### CROSS-REFERENCE TO RELATED APPLICATION

This application claims priority to Chinese Patent Application No. 201922313769. X, filed Dec. 20, 2019, which is incorporated herein by reference in its entirety.

### TECHNICAL FIELD

The present disclosure relates to the field of display technologies, and in particular, to a display panel and a display device.

### BACKGROUND

In a display panel, various signal lines can provide signals to support the display of the display panel. The signal lines include a plurality of datalines and a plurality of gate lines. The gate lines are used for providing a scan signal for sub-pixels of the display panel, and the data line is used for providing a data signal for the sub-pixels, so as to make the light emit light and make the display panel display images.

### SUMMARY

In one aspect, a display panel is provided. The display panel includes a plurality of signal lines, at least one conductive pattern, and a plurality of first switch units. Each of at least part of the signal lines is electrically connected to the at least one conductive pattern through at least one first switch unit; each first switch unit is connected between a corresponding signal line and a corresponding conductive pattern. The first switch unit includes a control portion and an electrostatic buffer portion. The control portion is electrically connected between the corresponding signal line and the electrostatic buffer portion, and is configured to close a line between the signal line and the electrostatic buffer portion in response to an electrostatic voltage of electrostatic charges conducted from the corresponding signal line. The electrostatic buffer portion includes a connecting sub-portion and an extension sub-portion; and the control portion, the corresponding conductive pattern and the extension sub-portion are electrically connected together through the connecting sub-portion.

In some embodiments, the control portion includes a first thin film transistor; a first electrode of the first thin film transistor is electrically connected to the corresponding signal line, and a second electrode of the first thin film transistor is electrically connected to a first end of the connecting sub-portion. A gate of the first thin film transistor is electrically connected to the first electrode of the first thin film transistor, or the gate of the first thin film transistor is a floating gate. The first switch unit further includes an insulating layer and a first via hole disposed in the insulating layer, the insulating layer is disposed between the second electrode and the gate of the first thin film transistor; the connecting sub-portion is electrically connected to the corresponding conductive pattern through the first via hole; a second end of the connecting sub-portion is electrically connected to the extension sub-portion

In some embodiments, the first electrode of the first thin film transistor is electrically connected to the gate of the first thin film transistor. The display panel further includes a plurality of second switch units. The corresponding signal line is further electrically connected to the corresponding conductive pattern through one second switch unit. Each second switch unit includes one second thin film transistor, a gate of the second thin film transistor is electrically connected to a first electrode of the second thin film transistor and the corresponding conductive pattern, and a second electrode of the second thin film transistor is electrically connected to the corresponding signal line; or, each second switch unit includes a plurality of second thin film transistors connected in series, a gate and a first electrode of each second thin film transistor are electrically connected; a gate and a first electrode of a second thin film transistor closet to the corresponding conductive pattern are electrically connected to the corresponding conductive pattern, and a second electrode of another second thin film transistor closet to the corresponding signal line is electrically connected to the corresponding signal line.

In some embodiments, the gate of the first thin film transistor and the corresponding conductive pattern are disposed in a same layer, and are made of a same material.

In some embodiments, an extending direction of each conductive pattern is substantially perpendicular to an extending direction of a signal line electrically connected thereto. The extension sub-portion extends in an extending direction of the corresponding conductive pattern electrically connected thereto.

In some embodiments, a length of the extension sub-portion in an extending direction thereof is greater than or equal to twice a width of the corresponding conductive pattern in a direction perpendicular to the extending direction of the corresponding conductive pattern.

In some embodiments, a length of the extension sub-portion in an extending direction thereof is greater than or equal to twice a width of the extension sub-portion perpendicular to the extending direction thereof.

In some embodiments, an orthographic projection of the extension sub-portion on a plane where the corresponding conductive pattern is located is in a shape of a rectangle.

In some embodiments, the first switch unit further includes at least one groove disposed in the insulating layer, the extension sub-portion includes at least one first portion disposed in the at least one groove, and a second portion disposed outside the at least one groove; a plane where a surface of each first portion facing away the corresponding conductive pattern is located is closer to the corresponding conductive pattern than a plane where a surface of the second portion facing away the corresponding conductive pattern is located.

In some embodiments, the insulating layer includes a first insulating sub-layer and a second insulating sub-layer, and the first insulating sub-layer is disposed on a side of the second insulating sub-layer proximate to the corresponding conductive pattern.

The electrostatic buffer portion further includes at least one buffer pattern disposed between the first insulating sub-layer and the second insulating sub-layer, and the extension sub-portion is electrically connected to the at least one buffer pattern through at least one second via hole disposed in the second insulating sub-layer. The buffer pattern is made of a semiconductor material or a conductor.

In some embodiments, the first thin film transistor further includes an active layer disposed between the first insulating sub-layer and the second insulating sub-layer, and the buffer pattern and the active layer are made of a same material.

In some embodiments, the display panel includes at least two conductive patterns. The plurality of signal lines include: a plurality of gate lines that are electrically connected to one of the at least two conductive patterns, and a plurality of data lines that are electrically connected to another of the at least two conductive patterns. An area of each gate lines is greater than an area of each data line, and an area of an extension sub-portion in a first switch unit electrically connected to the gate line is greater than an area of an extension sub-portion in a first switch unit electrically connected to the data line.

In some embodiments, the display panel further includes a common electrode line, and the at least one conductive pattern is electrically connected to the common electrode line.

In some embodiments, the display panel further includes at least one third switch unit, wherein the at least one conductive pattern is electrically connected to the common electrode line through the at least one third switch unit; each third switch unit includes one third thin film transistor. A first electrode of the third thin film transistor is electrically connected to the at least one conductive pattern, a second electrode of the third thin film transistor is electrically connected to the common electrode line; a gate and the first electrode of the third thin film transistor are electrically connected, or the gate of the third thin film transistor is a floating electrode.

In some embodiments, the display panel further includes at least one third switch unit, wherein the at least one conductive pattern is electrically connected to the common electrode line through the at least one third switch unit; each third switch unit includes a plurality of third thin film transistors connected in series. A first electrode of a third thin film transistor closet to the at least one conductive pattern is electrically connected to the at least one conductive pattern, a second electrode of a third thin film transistor closet to the common electrode line is electrically connected to the common electrode line; a gate and the first electrode of each third thin film transistor are electrically connected, or the gate of each third thin film transistor is a floating electrode.

In some embodiments, as shown in FIG. 7A, a width-to-length channel ratio of the third thin film transistor closet to the at least one conductive pattern is greater than a width-to-length channel ratio of a third thin film transistor farther away from the at least one conductive pattern.

In some embodiments, the at least one conductive pattern includes one conductive pattern, and each signal line is electrically connected to the conductive pattern through one first switching unit.

In some embodiments, the at least one conductive pattern includes two conductive patterns that are respectively arranged at two opposite sides of the plurality of signal lines, and the signal line is electrically connected to the two conductive patterns through two first switching units, respectively.

In another aspect, a display device is provided. The display device includes the display panel according to any of the above embodiments.

### BRIEF DESCRIPTION OF THE DRAWINGS

In order to describe technical solutions in the present disclosure more clearly, accompanying drawings to be used in some embodiments of the present disclosure will be introduced briefly. However, the accompanying drawings to be described below are merely accompanying drawings of some embodiments of the present disclosure, and a person of ordinary skill in the art may obtain other drawings according to these drawings.

In addition, the accompanying drawings to be described below may be regarded as schematic diagrams, and are not limitations on an actual size of a product, an actual process of a method and an actual timing of a signal involved in the embodiments of the present disclosure.

FIG. 1A is a schematic top view of a display panel, according to some embodiments;

FIG. 1B is a schematic structural diagram of a display panel, according to some embodiments:

FIG. 1C is a schematic structural diagram of another display panel, according to some embodiments;

FIG. 1D is a schematic structural diagram of yet another display panel, according to some embodiments;

FIG. 1E is a schematic structural diagram of yet another display panel, according to some embodiments;

FIG. 1F is a partially enlarged schematic diagram of the section F in FIG. 1E;

FIG. 2A is a schematic structural diagram of yet another display panel, according to some embodiments;

FIG. 2B is a partially enlarged schematic diagram of the section A1 in FIG. 2A, according to some embodiments;

FIG. 2C is a across section of a display panel taken along the line B-B′ in FIG. 2B, according to some embodiments:

FIG. 3A is a schematic structural diagram of yet another display panel, according to some embodiments;

FIG. 3B is a partially enlarged schematic diagram of the section A2 in FIG. 3A, according to some embodiments;

FIG. 3C is a across section taken along the line A-A′ in FIG. 3B, according to some embodiments;

FIG. 4A is a schematic structural diagram of yet another display panel, according to some embodiments;

FIG. 4B is a partially enlarged schematic diagram of the section A3 in FIG. 4A, according to some embodiments;

FIG. 5A is a partially enlarged schematic diagram of the section A1 in FIG. 2A, according to some embodiments;

FIG. 5B is a across section taken along the line C-C′ in FIG. 5A, according to some embodiments;

FIG. 5C is a across section taken along the line C-C′ in FIG. 5A, according to some embodiments;

FIG. 5D is a across section taken along the line C-C′ in FIG. 5A, according to some embodiments;

FIG. 6A is a partially enlarged schematic diagram of the section A1 in FIG. 2A, according to some embodiments;

FIG. 6B is a across section taken along the line D-D′ in FIG. 6A, according to some embodiments;

FIG. 6C is a across section taken along the line D-D′ in FIG. 6A, according to some embodiments;

FIG. 7A is a partially enlarged schematic diagram of a section E in FIG. 2A, according to some embodiments;

FIG. 7B is a partially enlarged schematic diagram of a section E in FIG. 2A, according to some embodiments;

FIG. 7C is a schematic structural diagram of a switch unit, according to some embodiments; and

FIG. 7D is a schematic structural diagram of another switch unit, according to some embodiments.

### DETAILED DESCRIPTION

Technical solutions in some embodiments of the present disclosure will be described clearly and completely in combination with the accompanying drawings. However, the described embodiments are merely some but not all embodiments of the present disclosure. Based on the embodiments provided by the present disclosure, all other embodiments obtained by a person of ordinary skill in the art belong to the protection scope of the present disclosure.

Unless the context requires otherwise, throughout the description and the claims, the term “comprise” and other forms thereof such as the third-person singular form “comprises” and the present participle form “comprising” are construed in an open and inclusive sense, i.e., “include, but not limited to”. In the description, terms such as “one embodiment”, “some embodiments”, “exemplary embodiments”, “example”, “specific example”, or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Terms such as “first” and “second” are used for descriptive purposes only, and are not to be construed as indicating or implying the relative importance or implicitly indicating the number of indicated technical features below. Thus, features defined by “first” and “second” may explicitly or implicitly include one or more of the features. In the description of the embodiments of the present disclosure, the term “a/the plurality of” means two or more unless otherwise specified.

In the description of some embodiments, the term such as “connected” and their extensions may be used. For example, the term “connected” may be used in the description of some embodiments to indicate that two or more components are in direct physical or electrical contact with each other. The embodiments disclosed herein are not necessarily limited to the contents herein.

“At least one of A, B, and C” has a same meaning as “at least one of A, B, or C”, and both include the following combinations of A, B, and C: only A, only B, only C, a combination of A and B, a combination of A and C, a combination of B and C, and a combination of A, B, and C.

The phrase “A and/or B” includes the following three combinations: only A, only B, and a combination of A and B.

As used herein, “about” or “approximately” includes the stated value and the average value that is within an acceptable deviation range of a specific value. The acceptable deviation range is determined by a person of ordinary skill in the art in view of measurement in question and errors associated with measurement of a specific quantity (i.e., limitations of a measurement system). Technical solutions in some embodiments of the present disclosure will be described clearly and completely in combination with the accompanying drawings. However, the described embodiments are merely some but not all embodiments of the present disclosure. Based on the embodiments provided by the present disclosure, all other embodiments obtained by a person of ordinary skill in the art belong to the protection scope of the present disclosure.

In a display panel of the related art, a thin film transistor is electrically connected between a signal line and a conductive pattern. When the signal line generates electrostatic charges, an electrostatic voltage of the generated electrostatic charges may turn on the thin film transistor, so that the electrostatic charges on the signal line may be conducted to the conductive pattern. In this way, damage caused by electrostatic charge discharge (ESD) to the signal lines and components connected thereto may be reduced. However, in a case where there are a large amount of electrostatic charges generated on the signal line, when the electrostatic charges are conducted to the conductive pattern through the thin film transistor, due to a limited capability of the thin film transistor to buffer the electrostatic charges, a large electrostatic current may flow through the thin film transistor, which may cause the thin film transistor to be easily burned out.

Some embodiments of the present disclosure provide a display device, and the display device may be a liquid crystal display (LCD) display device, an organic light-emitting diode (OLED) display device, a micro light-emitting diode (Micro LED) display device, or a mini light-emitting diode (Mini LED) display device. The display device may be any product or component with a display function, such as a monitor, a TV, a digital camera, a mobile phone, or a tablet computer.

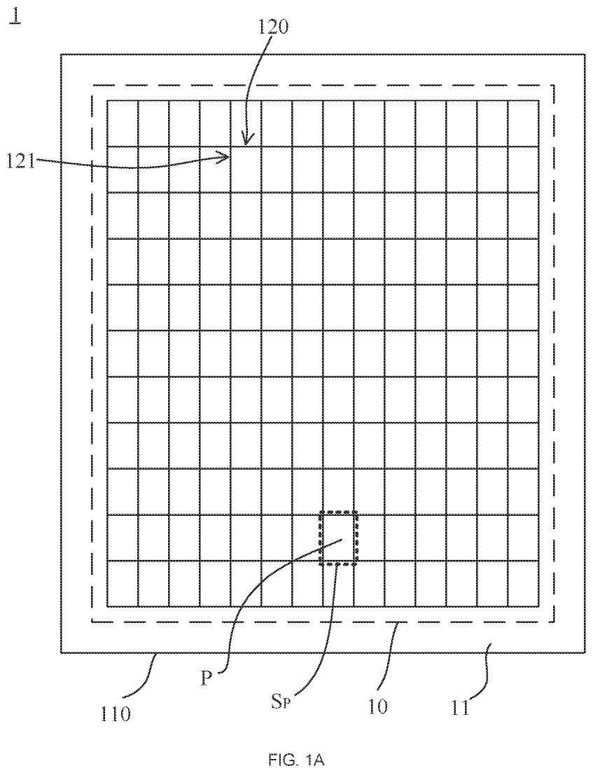

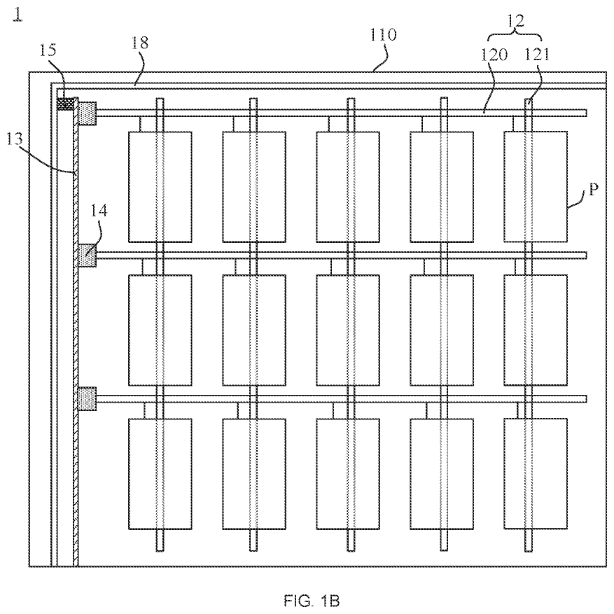

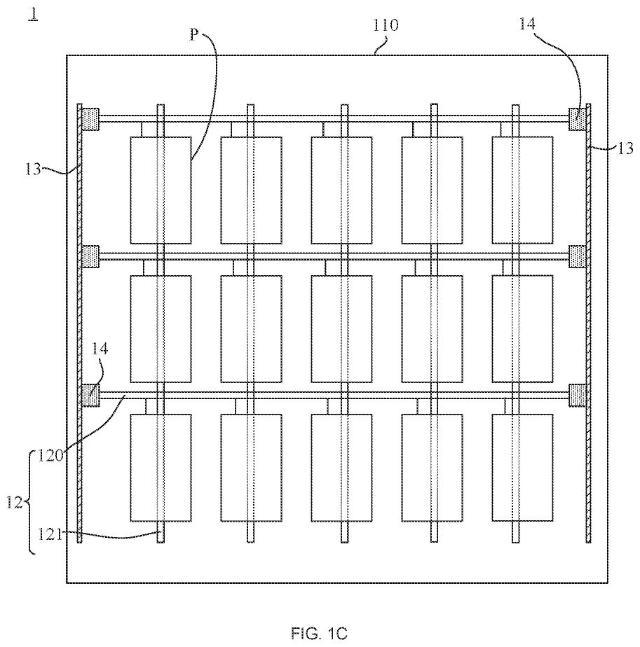

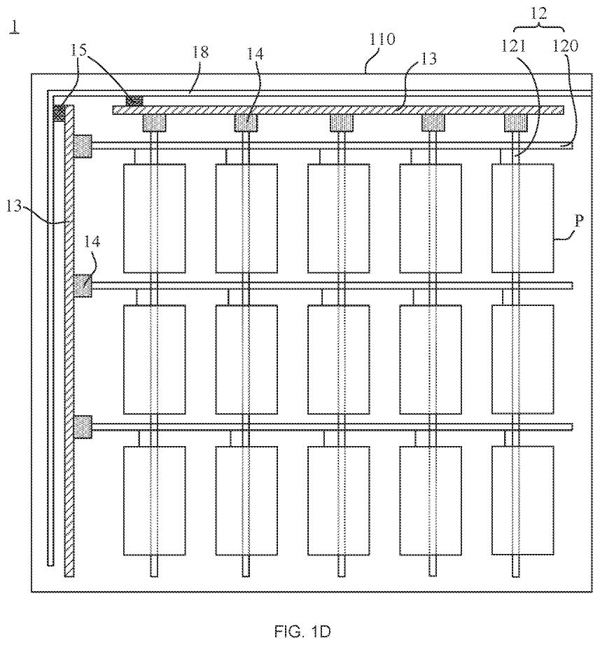

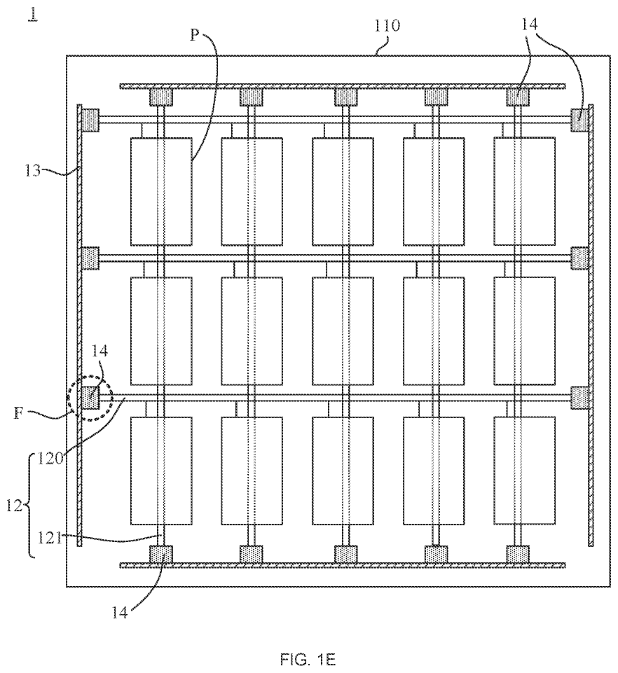

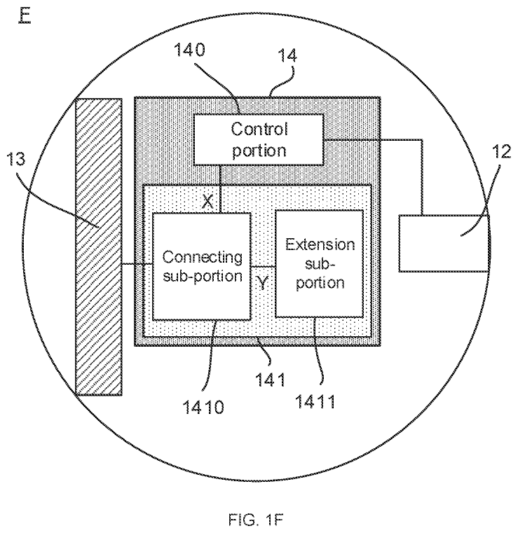

The display device at least includes a display panel. As shown in FIG. 1A, a display panel 1 includes an active area 10 and a peripheral region 11. The peripheral region 11 is disposed on at least one side of the active area 10. For example, as shown in FIG. 1A, the peripheral region 11 is disposed around the active area 10. The display device includes a plurality of sub pixels P of different colors provided in the active area 10, and the sub pixels P at least include a first color sub-pixel, a second color sub-pixel, and a third color sub-pixel. The first color, the second color, and the third color are three primary colors (e.g., red, green and blue, respectively). FIG. 1A shows an example in which the sub-pixels P are arranged in an array.

As shown in FIGS. 1A to 1F, the display panel 1 includes a base 110 which plays a supporting role, and a plurality of signal lines 12, at least one conductive pattern 13 and a plurality of first switch units 14 that are disposed on the base 110.

The base 110 may be a base without any layer provided thereon, or a base on which at least one layer is provided. For example, the base 110 includes a glass base, and an inorganic buffer layer provided on the glass base.

In some embodiments, as shown in FIGS. 1B and 1C, each of part of the signal lines 12 is electrically connected to the at least one conductive pattern 13 through at least one first switch unit 14.

For example, as shown in FIG. 1B, the display panel 1 includes one conductive pattern 13 arranged at one side of the signal lines 12. Each of part of the signal lines 12 is electrically connected to the conductive pattern 13 through one first switch unit 14.

For another example, as shown in FIG. 1C, the display panel 1 includes two conductive patterns 13 which are arranged at two opposite sides of the signal lines 12, respectively. Each of part of the signal lines 12 is electrically connected to the two conductive patterns 13 through two first switch units 14. Each first switch units 14 is electrically connected between a corresponding conductive pattern 13 and a corresponding signal line 12.

In some other embodiments, as shown in FIGS. 1D and 1E, each of the plurality of signal lines 12 is electrically connected to the at least one conductive pattern 13 through at least one first switch unit 14. That is, all the signal lines 12 are electrically connected to the at least one conductive pattern 13.

For example, as shown in FIG. 1D, the display panel 1 includes two conductive patterns 13 which are arranged at two adjacent sides of the signal lines 12. Each signal line 12 is only electrically connected to one conductive pattern 13 through one first switch unit 14.

For another example, as shown in FIG. 1E, the display panel 1 includes four conductive patterns 13 each of which is arranged at a respective side of the signal lines 12, which means that the conductive patterns 13 are arranged around the active area 10.

Each signal line 12 is electrically connected to two conductive patterns 13 that are arranged on two opposite sides of the signal lines 12 through two first switch units 14. Each first switch unit 14 is electrically connected between a corresponding conductive pattern 13 and a corresponding signal line 12.

It will be understood that a number of the at least one conductive pattern 13 may be set according to actual needs.

The at least one conductive pattern 13 may be in a shape of a regular pattern. For example, as shown in FIGS. 1B to 1E, the conductive pattern 13 is in a shape of a rectangle. Of course, it also possible that the at least one conductive pattern 13 is in a shape of an irregular pattern.

The at least one conductive pattern 13 is made of a conductive material. For example, a material of the at least one conductive pattern 13 includes at least one of a metal conductive material or a metal oxide conductive material. In a case where the material of the at least one conductive pattern 13 includes the metal conductive material, it may include at least one of aluminum (A1), copper (Cu), molybdenum (Mo) or silver (Ag). In a case where the material of the at least one conductive pattern 13 is the metal oxide conductive material, it may include at least one of indium tin oxide (ITO) or indium zinc oxide (IZO).

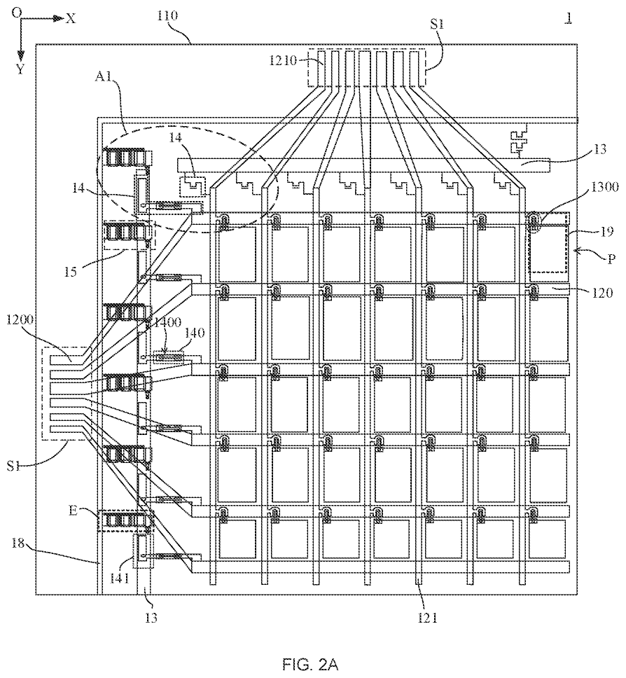

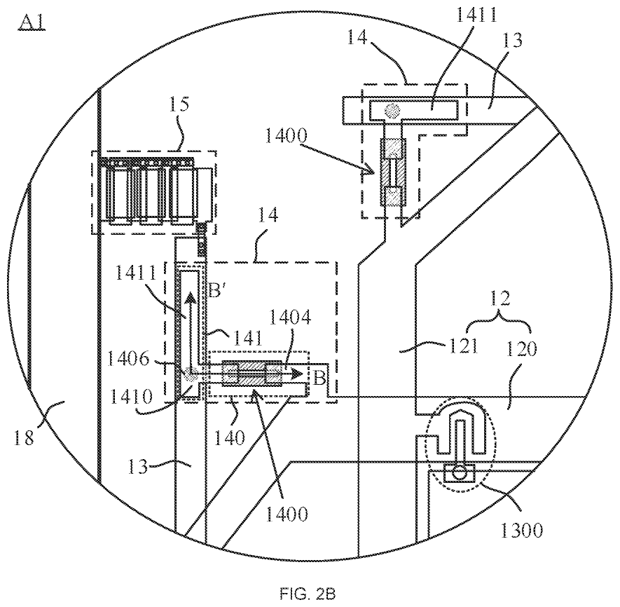

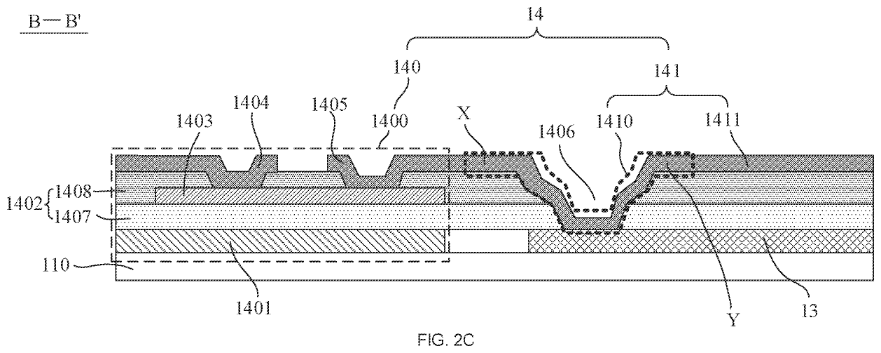

In some embodiments, as shown in FIGS. 1B, 1C, 1D, 1E, 2A and 2B, the plurality of signal lines 12 include a plurality of first signal lines 120 (such as gate lines) extending in a row direction of a sub-pixel array consisting of the sub-pixels described above, and second signal lines 121 (such as, data lines) extending in a column direction of the sub-pixel array.

For example, in a case where the first signal lines 120 are the gate lines and the second signal lines 121 are the data lines, as shown in FIG. 1A, orthographic projections of the gate lines and the data lines on the base 110 intersect to enclose a plurality of regions S_{P}, each of which is a region where a sub-pixel P is located. The region S_{P} includes alight-emitting region of a corresponding sub-pixel P. Referring to FIG. 2A, each sub-pixel P includes a pixel driver circuit 19, and the pixel driver circuit 19 includes at least one thin film transistor 1300 and a capacitor electrically connected to the thin film transistor 1300.

For example, the thin film transistor 1300 includes a gate, an active layer, and a source-drain metal layer (including a first electrode and a second electrode) sequentially disposed in a thickness direction of the thin film transistor 1300, and each of the first electrode and the second electrode is in electrical contact with the active layer. Referring to FIG. 2B, the gate of the thin film transistor 1300 is electrically connected to a corresponding gate line, and the first electrode is electrically connected to a corresponding data line. The thin film transistor 1300 may write a data signal transmitted by the corresponding dataline into the capacitor in response to a scan signal transmitted by the corresponding gate line.

The display panel 1 may further include components such as a source driver and a gate driver disposed in the peripheral region 11.

In some embodiments, as shown in FIG. 2A, in the case where the first signal lines 120 are gate lines, and the second signal lines 121 are signal lines, one end of each gate line is connected to a gate line leading-out terminal 1200 provided in the peripheral region 11, and one end of each data line is connected to a data line leading-out terminal 1210 provided in the peripheral region 11. Connection portions are provided to be electrically connected between each gate line leading-out terminal 1200 and a corresponding gate line, and between each data line leading-out terminal 1210 and a corresponding data line. In this way, the corresponding gate line are leaded from the active area 10 to the peripheral region 11 to be electrically connected to the gate driver, and the corresponding data line are leaded from the active area 10 to the peripheral region 11 to be electrically connected the source driver. For example, at least part of the connection portions are inclined connection portions.

In some embodiments, as shown in FIG. 2A, an orthographic projection of a conductive pattern 13 electrically connected to the first signal lines 120 is located between orthographic projections of the gate line leading-out terminals 1200 and orthographic projections of the first signal lines 120, and an orthographic projection of a conductive pattern 13 electrically connected to the second signal lines 121 is located between orthographic projections of the data line leading-out terminals 1210 and orthographic projections of the second signal lines 121.

Here, a material of the signal lines 12 may include, for example, at least one of Cu, Mo, Al, or Ag. The signal line 12 may be of a single-layer structure, or a multi-layer structure such as a three-layer structure of Mo—Al—Mo.

In the case where the first signal line 120 is the gate line and the second signal line 121 is the data line, the gate line and the data line may be made of a same material, or different materials, which is not limited.

In some embodiments, as shown in FIG. 2A, the display panel 1 further includes a common electrode line 18 provided in the peripheral region 11. An orthographic projection of the at least one conductive pattern 13 and orthographic projections of the connection portions have overlapping regions, and an orthographic projection of a common electrode line 18 and the orthographic projections of the connection portions have overlapping regions, but the at least one conductive pattern 13 and the connection portions are insulated from each other, and the common electrode line 18 and the connection portions are insulated from each other. For example, the connection portions may be disposed in a different layer from the at least one conductive pattern 13 and the common electrode line 18.

In some embodiments, as shown in FIG. 1F, each first switch unit 14 includes a control portion 140 and an electrostatic buffer portion 141. The control portion 140 is electrically connected between a corresponding signal line 12 and the electrostatic buffer portion 141, and the control portion 140 is configured to close a line between the corresponding signal line 12 and the electrostatic buffer portion 141 in response to an electrostatic voltage of electrostatic charges that are conducted from the signal line 12. That is, when there are electrostatic charges generated on the signal line 12 and the electrostatic charges are conducted from the signal line 12 to the control portion 140, the control portion 140 will close the line between the corresponding signal line 12 and the electrostatic buffer portion 141.

The electrostatic buffer portion 141 includes a connecting sub-portion 1410 and an extension sub-portion 1411, and the control portion 140, the corresponding conductive pattern 13 and the extension sub-portion 1411 are electrically connected together through the connecting sub-portion 1410.

The extension sub-portion 1411 of the electrostatic buffer portion 141 is electrically connected to the control portion 140 through the connecting sub-portion 1410. That is, in a case where there are electrostatic charges generated on the signal line 120, and the control portion 140 close the line between the corresponding signal line 12 and the electrostatic buffer portion 141, the extension sub-portion 1411, the connecting sub-portion 1410 and the control portion 140 are all distributed with the electrostatic charges. In this way, by providing the electrostatic buffer portion 141, it is equivalent to increasing an area in the first switch unit 14 available for electrostatic charge distribution, which may increase resistance of the first switch unit 14. Accordingly, an electrostatic current flowing through the first switch unit 14 may be decreased. Therefore, it may reduce a risk that the thin film transistor in the control portion 140 is burned out. As a result, a buffering effect of the first switch unit 14 against the electrostatic charges may be improved, so that reliability of the display panel 1 may be improved.

It will be understand that, since the electrostatic charges are conducted to the conductive pattern 13 through the first switch unit 14, a potential at the electrostatic buffer portion 141 in the first switch unit 14 is substantially equal to a potential at the corresponding conductive pattern 13. The larger an area of the connecting sub-portion 1410 is, and/or the larger an area of the extension sub-portion 1411 is, the better the buffering effect of the first switch unit 14 against the electrostatic charges may be.

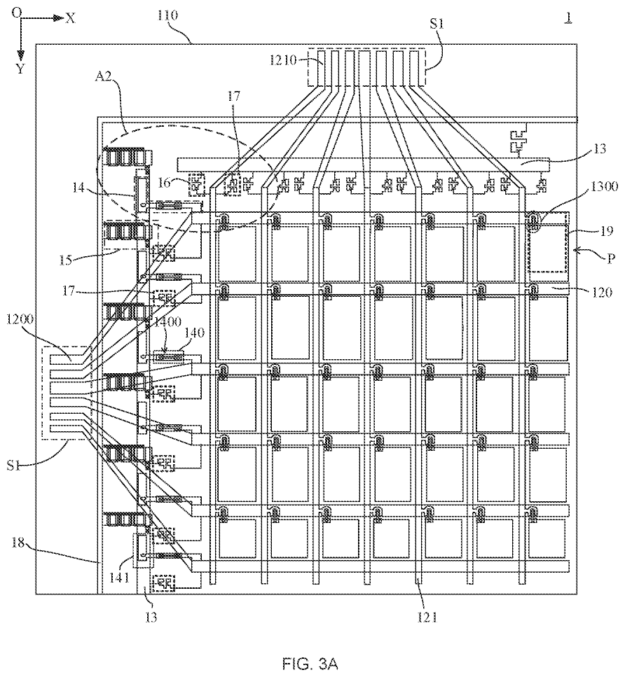

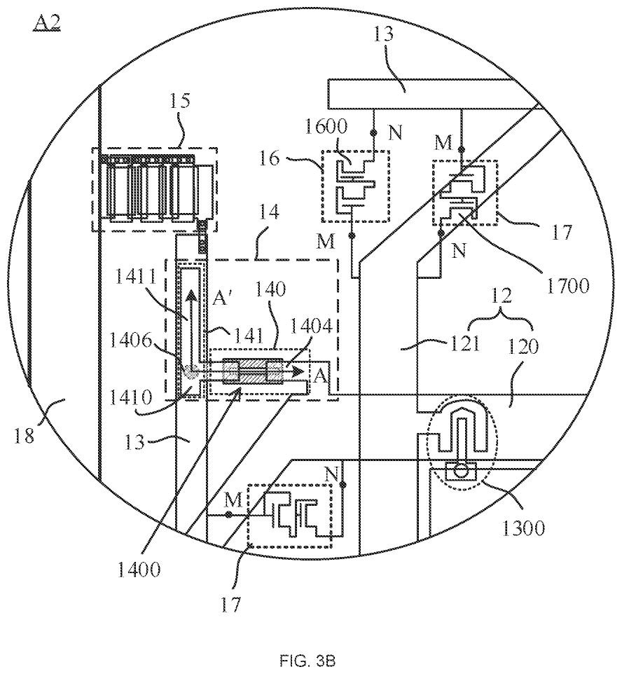

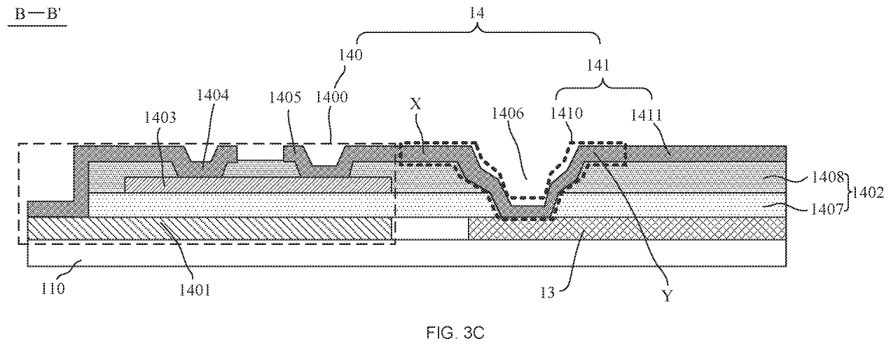

In some embodiments, referring to FIGS. 2A to 3C, the control portion 140 includes a first thin film transistor 1400. In the first thin film transistor 1400, a first electrode 1404 is electrically connected to the signal line 12, and a second electrode 1405 that is in a same layer with the first electrode 1404 is electrically connected to a first end X of the connecting sub-portion 1410. The first switch unit 14 further includes an insulating layer 1402 and a first via hole 1406 disposed in the insulating layer 1402. The insulating layer 1402 is disposed between the second electrode 1405 and a gate 1401 of the first thin film transistor 1400. The connecting sub-portion 1410 is electrically connected to the corresponding conductive pattern 13 through the first via hole 1406, and a second end Y of the connecting sub-portion 1410 is electrically connected to the extension sub-portion 1411.

For example, referring to FIGS. 2C, 5B, 5C and 6B, the gate 1401 of the first thin film transistor 1400 is a floating gate. That is, the gate 1401 is not electrically connected to any other component or structure such as the signal line 12, the second electrode 1404, the first electrode 1405, or the conductive pattern 13, and the gate 1401 is in an independent and insulated state.

In this case, orthographic projections of the first electrode 1404 and the gate 1401 have a first overlapping region, and there is a capacitor including a portion of the gate 1401 and a portion of the first electrode 1404 in the first overlapping region. When the electrostatic charges are generated on the signal line 12, since the first electrode 1404 of the first thin film transistor 1400 is electrically connected to the signal line 12, part of the electrostatic charges may move to the first electrode 1404. Therefore, electrostatic charges on the first electrode 1404 may cause induced charges to be generated on the gate 1401. In this way, the first thin film transistor 1400 is turned on in response to an induced voltage of the induced charges on the gate 1401.

It will be noted that, in the case where the gate 1401 of the first thin film transistor 1400 is the floating gate, orthographic projections of the gate 1401 and the second electrode 1405 may have a second overlapping region. That is, there is another capacitor including the gate 1401 and the second electrode 1405 in the second overlapping region. In this case, the first thin film transistor 1400 may realize a bidirectional transmission of electrostatic charges. That is, the electrostatic current may flow from the first electrode 1404 to the second electrode 1405, or from the second electrode 1405 to the first electrode 1404 of the first thin film transistor 1400. In this way, whether there are electrostatic charges to be conducted from the signal line 12 to the corresponding conductive pattern 13, or electrostatic charges to be conducted from the corresponding conductive pattern 13 to the signal line 12, the first thin film transistor 1400 may be turned on.

For another example, as shown in FIGS. 3C, 5D and 6C, the gate 1401 of the first thin film transistor 1400 is electrically connected to the first electrode 1404 of the first thin film transistor 1400.

In this case, both the first electrode 1404 and the gate 1401 are electrically connected to the signal line 12. Therefore, when electrostatic charges are generated on the signal line 12, the gate 1401 is distributed with the electrostatic charges due to its electrical connection with the signal line 12. That is, there is an electrostatic voltage generated on the gate 1401, which may turn on the first thin film transistor 1400, so that the electrostatic charges may be conducted to the corresponding conductive pattern 13 from the signal line 12.

It will be noted that, the first electrode 1404 and the second electrode 1405 of the first thin film transistor 1400 may be made of metal materials. For example, materials of the first electrode 1404 and the second electrode 1405 may include at least one of Cu, Mo, Al, or Ag. The gate 1401 of the first thin film transistor 1400 may be made of a metal material, for example, a material of the gate 1401 may include at least one of Ag or Al.

In some embodiments, as shown in FIGS. 2C and 2D, the corresponding conductive pattern 13 and the gate 1401 of the first thin film transistor 1400 are disposed in a same layer, and are made of a same material. That is, the corresponding conductive pattern 13 and the gate 1401 may be formed through a same second patterning process, which may include a photoetching process includes, for example, exposure and development, and/or an etching process.

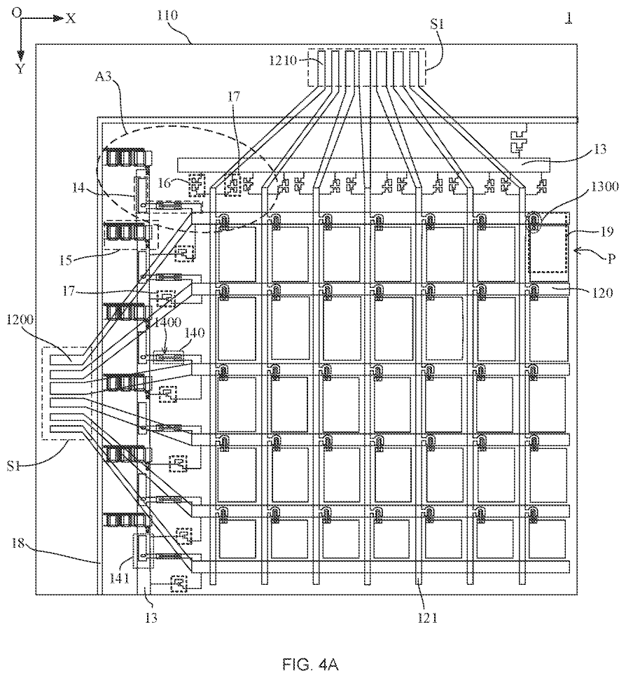

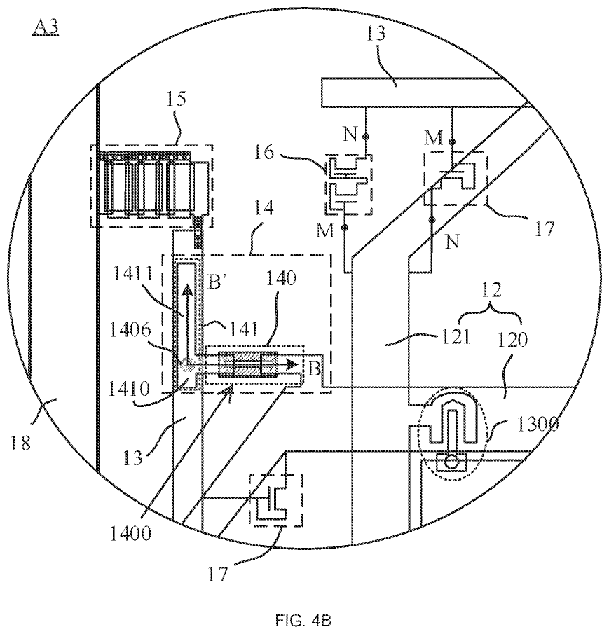

In some embodiments, in the case where the gate 1401 and the first electrode 1404 of the first thin film transistor 1400 are electrically connected, as shown in FIGS. 3A to 4, the display panel 1 further includes a plurality of second switch units 17. The signal line 12 is further electrically connected to the corresponding conductive pattern 13 through one second switch unit 17. For example, referring to FIGS. 3B and 4B, a first end M of the second switch unit 17 is electrically connected to the at least one conductive pattern 13, and a second end N of the second switch unit 17 is electrically connected to a corresponding signal line 12.

Referring to FIGS. 3A, 3B, 4A and 4B, the second switch unit 17 includes at least one second thin film transistor 1700.

For example, referring to FIGS. 4A and 4B, the second switch unit 17 includes one second thin film transistor 1700, and a gate of the second thin film transistor 1700 is electrically connected to a first electrode of the second thin film transistor 1700 and the corresponding conductive pattern 13, and a second electrode of the thin film transistor is electrically connected to the signal line 12.

In other examples, referring to FIGS. 3A and 3B, the second switch unit 17 includes a plurality of second thin film transistors 1700 connected in series, and a gate of each second thin film transistor 1700 is electrically connected to a first electrode of thereof. A gate and a first electrode of a second thin film transistor 1700 closet to the corresponding conductive pattern 13 are electrically connected to the corresponding conductive pattern 13, and a second electrode of another second thin film transistor 1700 closet to the signal line 12 is electrically connected to the signal line 12.

It will be noted that, that the second thin film transistors 1700 connected in series refers to that the second thin film transistors 1700 are electrically connected in sequence. Taking the second switch unit 17 electrically connected to the first signal line 120 in FIG. 3B as an example, it includes two second thin film transistors 1700. For ease to describe, in a direction from left to right in the figure, the two second thin film transistors 1700 are named a left thin film transistor and a right thin film transistor, respectively. A second electrode of the left thin film transistor is electrically connected to a first electrode of the right thin film transistor.

In the display panel 1, the insulating layer 1402 may be made of an inorganic material. For example, a material of the insulating layer 1402 includes at least one of silicon oxide, silicon nitride, or silicon oxynitride.

The material of the insulating layer 1402 may also be made of an organic material. For example, the material of the insulating layer 1402 includes polyimide.

In some embodiments, the insulating layer 1402 may include one layer or multiple layers. For example, as shown in FIGS. 2C, 3C, 5B to 5D, 6B and 6C, the insulating layer 1402 includes a first insulating sub-layer 1407 and a second insulating sub-layer 1408.

The first insulating sub-layer 1407 is disposed on a side of the second insulating sub-layer 1408 proximate to the conductive pattern 13. Here, the first insulating sub-layer 1407 and the second insulating sub-layer 1408 may be made of inorganic materials and/or organic materials, which is not limited.

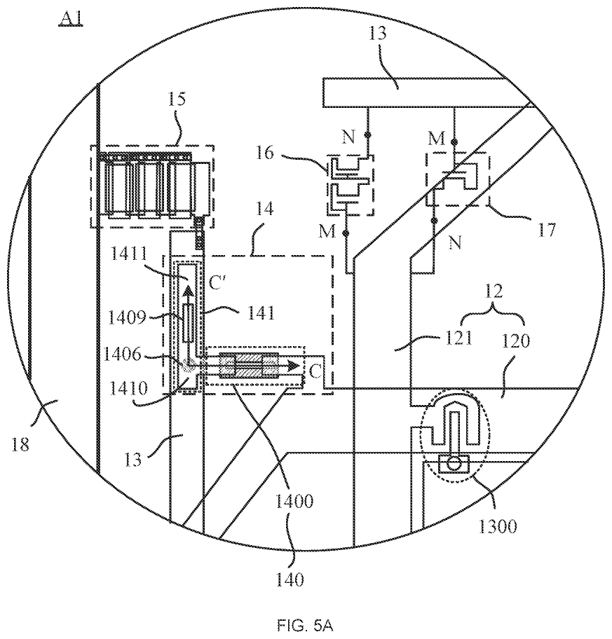

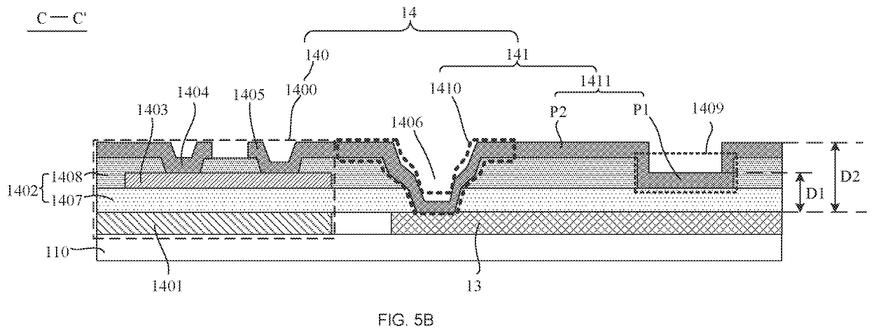

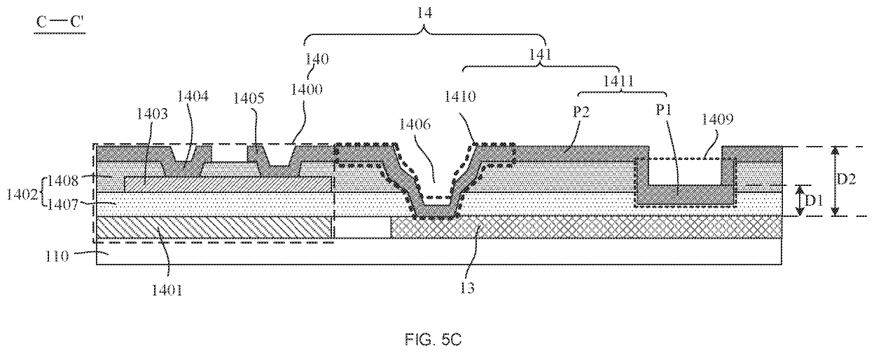

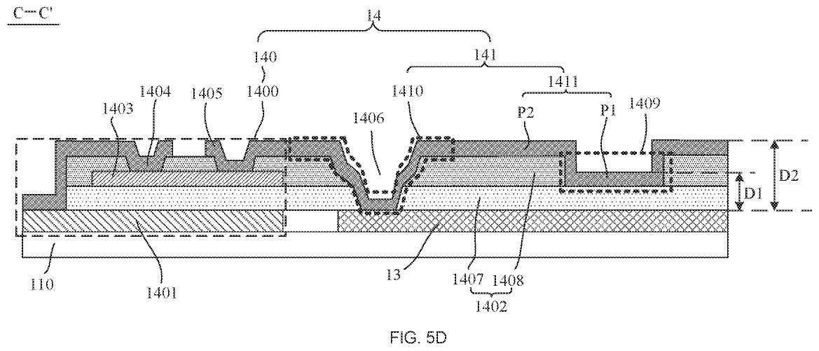

In some embodiments, as shown in FIGS. 5A to 5D, the first switch unit 14 further includes at least one groove 1409 disposed in the insulating layer 1402, and the extension sub-portion 1411 includes at least one first portion P1 disposed in the at least one groove 1409, and a second portion P2 disposed outside the at least one groove 1409. A plane where a surface of each first portion P1 facing away the corresponding conductive pattern 13 is located is closer to the corresponding conductive pattern 13 than a plane where a surface of the second portion P2 facing away the corresponding conductive pattern 13 is located.

In this case, a maximum distance D1 between the surface of each first portion P1 facing away the corresponding conductive pattern 13 and the corresponding conductive pattern 13 may be less than a distance D2 between a surface of the second portion P2 facing away the corresponding conductive pattern 13 and the corresponding conductive pattern 13.

In this way, providing the at least one groove 1409 on the insulating layer 1402 may increase a length of the extension sub-portion 1411. That is, in a case where a width of the extension sub-portion 1411 is certain, an area of the extension sub-portion 1411 may be increased, thereby further increasing the buffering effect of the first switch unit 14 against the electrostatic charges. In addition, the larger a depth of the groove 1409 is, the larger the area of the extension sub-portion 1411 is, and the stronger the electrostatic buffering capability of the first switch unit 14 is.

For example, as shown in FIGS. 5B to 5D, the groove 1409 dose not penetrate the insulating layer 1402.

Of course, in some other examples, it is possible that the groove 1409 penetrates the insulating layer 1402 to expose the corresponding conductive pattern 13. In this case, the extension sub-portion 1411 may further be electrically connected to the corresponding conductive pattern 13 through the groove 1409 penetrating the insulating layer 1402.

In some embodiments, as shown in FIGS. 5B and 5D, a depth of the groove 1409 may be substantially equal to a thickness of the second insulating sub-layer 1408. In some other embodiments, as shown in FIG. 5C, the depth of the groove 1409 may be greater than the thickness of the second insulating sub-layer 1408, and less than a thicknesses of the insulating layer 1402.

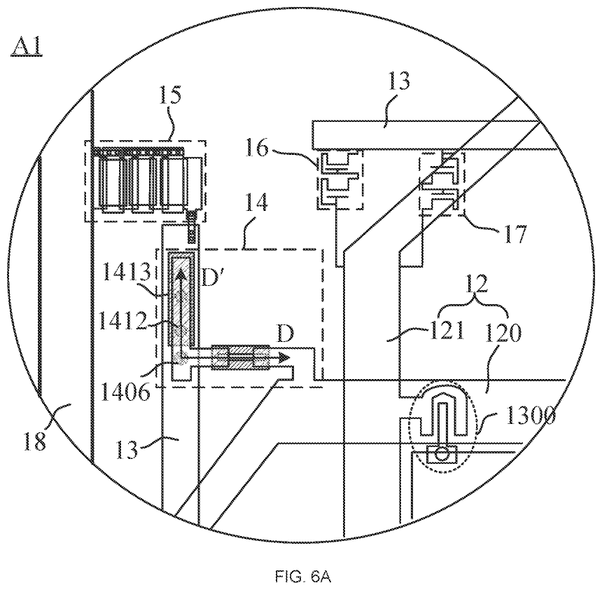

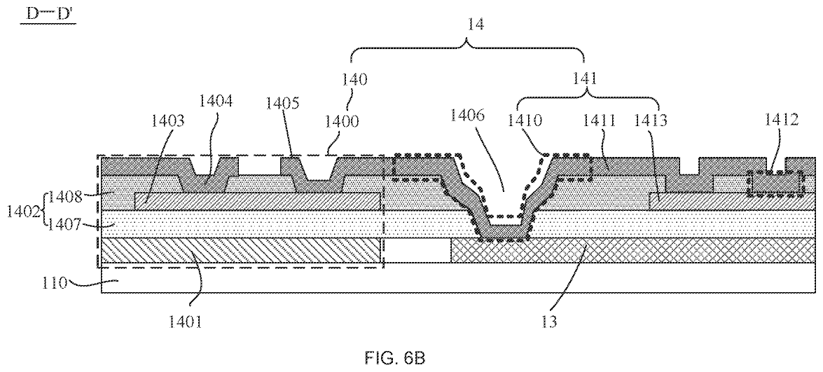

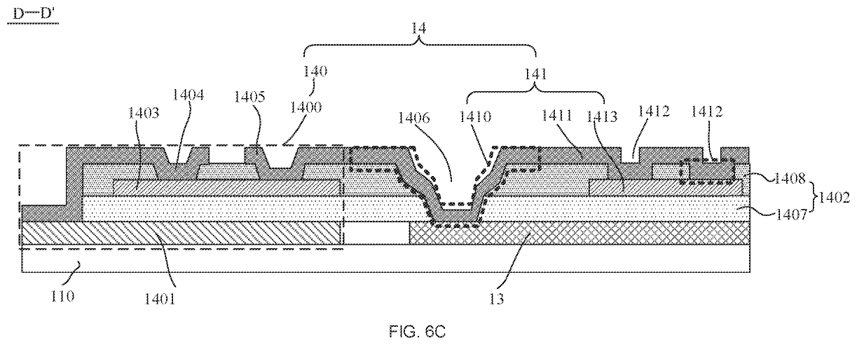

In some embodiments, as shown in FIGS. 6A to 6C, the electrostatic buffer portion 141 further includes at least one buffer pattern 1413 disposed between the first insulating sub-layer 1407 and the second insulating sub-layer 1408. At least one second via hole 1412 is disposed in the second insulating sub-layer 1408, and the extension sub-portion 1411 is electrically connected to the at least one buffer pattern 1413 through the at least one second via hole 1412. For example, as shown in FIG. 6B, extension sub-portion 1411 is electrically connected to the buffer pattern 1413 through two second via hole 1412.

A material of the buffer pattern 1413 may include, for example, a semiconductor material or a conductor material. The semiconductor material may include, for example, at least one of amorphous silicon or polysilicon. The conductor material may include, for example, at least one of Ag or Al.

In a process of the electrostatic charges being conducted to the conductive pattern 13, since the at least one buffer pattern 1413 is electrically connected to the extension sub-portion 1411, the electrostatic charges distributed on the extension sub-portion 1411 may be conducted to the buffer pattern 1413. As a result, it is possible to further increase the area in the first switch unit 14 available for electrostatic charge distribution, which may further reduce the electrostatic voltage and electrostatic current, and enhance the buffering effect of the first switch unit 14 against the electrostatic charges.

Since the at least one buffer pattern 1413 is located between the first insulating sub-layer 1407 and the second insulating sub-layer 1408, there may be enough space in the first switch unit 14 for the buffer pattern 1413 with large area to be arranged, which may increase the area in the first switch unit 14 available for the electrostatic charge distribution.

In some embodiments, as shown in FIGS. 6B and 6C, the first thin film transistor 1400 further includes an active layer 1403 disposed between the first insulating sub-layer 1407 and the second insulating sub-layer 1408. For example, the active layer 1403 are in electrical contact with the second electrode 1405 and the first electrode 1403 through via holes located in the second insulating sub-layer 1408. In this case, the at least one buffer pattern 1413 and the active layer 1403 of the first thin film transistor 1400 are disposed in a same layer, and may be made of a same material. That is, the at least one buffer pattern 1413 and the active layer 1403 of the first thin film transistor 1400 may be manufactured through a same first patterning process, which may simplify the manufacturing process of the display panel 1.

In some embodiments, referring to FIGS. 1B to 1E, 2A, 3A and 4A, an extending direction of each conductive pattern 13 is substantially perpendicular to an extending direction of a signal line 12 electrically connected thereto. For example, as shown in FIGS. 2A, 3A and 4A, in the case where the signal lines 12 include the first signal lines 120 that extend in a direction OX, and the second signal lines 121 that extend in a direction OY, an extending direction of a conductive pattern 13 electrically connected to the first signal lines 120 is substantially perpendicular to the direction OX, and an extending direction of a conductive pattern 13 electrically connected to the second signal lines 121 is substantially perpendicular to the direction OY.

In some embodiments, as shown in FIGS. 2B, 3B, 4B, 5A and 6A, the extension sub-portion 1411 extends in an extending direction of the corresponding conductive pattern 13 electrically connected thereto (i.e., the direction OY).

On this basis, for example, a length of the extension sub-portion 1411 in its extending direction is greater than or equal to twice a width of the corresponding conductive pattern electrically connected thereto in a direction perpendicular to the extending direction of the corresponding conductive pattern 13 (i.e., the direction OX). It will be noted that, a potential at the extension sub-portion 1411 is approximately equal to a potential at the corresponding conductive pattern 13, and the larger the area of the extension sub-portion 1411 is, the better the buffering effect of the first switch unit 14 against electrostatic charges may be. The length of the extension sub-portion 1411 may be set with the width of the conductive pattern 13 as a reference in a case where the width of the extension sub-portion 1411 is unchanged, so as to increase the area of the extension sub-portion 1411.

In some embodiments, as shown in FIGS. 2B, 3B, 4B, 5A and 6A, the length of the extension sub-portion 1411 in its extending direction is greater than or equal to twice the width of the extension sub-portion 1411 perpendicular to its extending direction thereof.

Here, the extension sub-portion 1411 may be in a shape of a regular pattern or an irregular pattern, which is not limited. For example, as shown in FIGS. 2B, 3B, 4B, 5A and 6A, the shape of the extension sub-portion 1411 is rectangular.

In some embodiments, referring to FIGS. 1D, 1E and 2A, in the case that the display panel 1 includes at least two conductive patterns 13, the plurality of first signal lines 120 include the gate lines that are electrically connected to one of the at least two conductive patterns 13, and the plurality of second signal lines 121 include the date lines that are electrically connected to another of the at least two conductive patterns 13. An area of each of at least part of the gate lines 120 is greater than an area of each data lines 121. In this case, as shown in FIG. 2B, an area of an extension sub-portion 1411 in a first switch unit 14 electrically connected to each gate line 120 in the part of the gate lines 120 is greater than an area of the extension sub-portion 1411 in a first switch unit 14 electrically connected to the data line 121.

For example, in a case where an area of each gate line is greater than the area of each data line, an area of an extension sub-portion 1411 in a first switch unit 14 electrically connected to the gate line is greater than the area of the extension sub-portion 1411 in the first switch unit 14 electrically connected to the data line 121.

Since the area of the gate line is greater than the area of the data line, electrostatic charges generated on the gate line may be more than electrostatic charges generated on the data line. Accordingly, an electrostatic voltage on an input terminal of the first switch unit 14 electrically connected to the gate line may be greater than an electrostatic voltage on an input terminal of the first switch unit 14 electrically connected to the data line. By setting the area of the extension sub-portion 1411 corresponding to the gate line to be greater than the area of the extension sub-portion 1411 corresponding to the data line, it is possible to ensure that the first switch unit 14 corresponding to the gate line has a bettering effect against the electrostatic charges, which may prevent a large electrostatic current from flowing through the first switch unit 14 in a process of the electrostatic charges being conducted to the conductive patterns 13.

In some embodiments, as shown in FIGS. 2A, 3A and 4A, the display panel 1 further includes a common electrode line 18, and the at least one conductive pattern 13 is electrically connected to the common electrode line 18. It will be noted that, the common electrode line 18 may be made of a conductive material, such as a metal material. For example, the common electrode line 18 is made of Ag and/or Al.

For example, the common electrode is grounded. In this case, a voltage of the common electrode line 18 is 0 V.

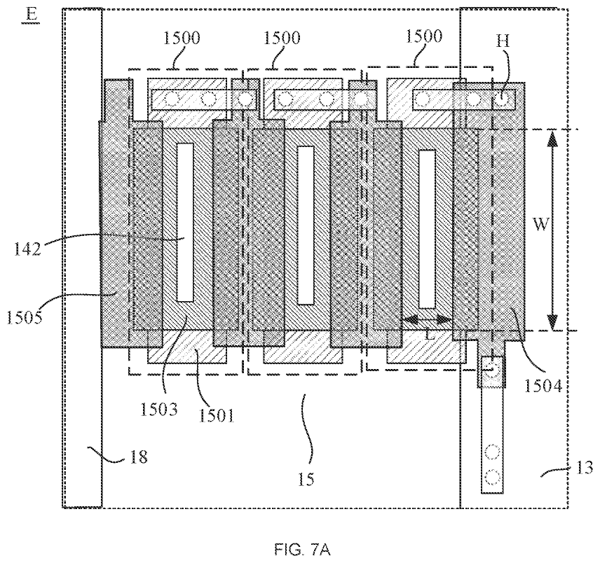

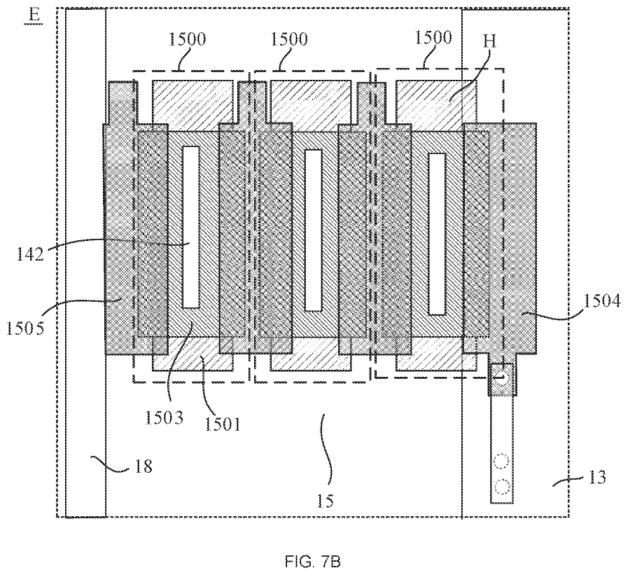

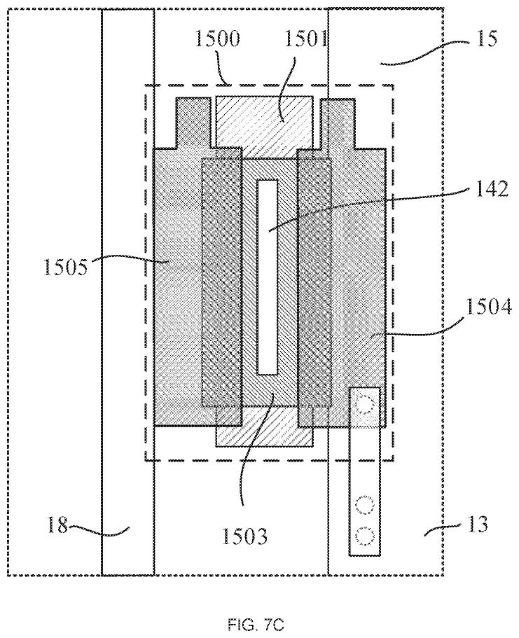

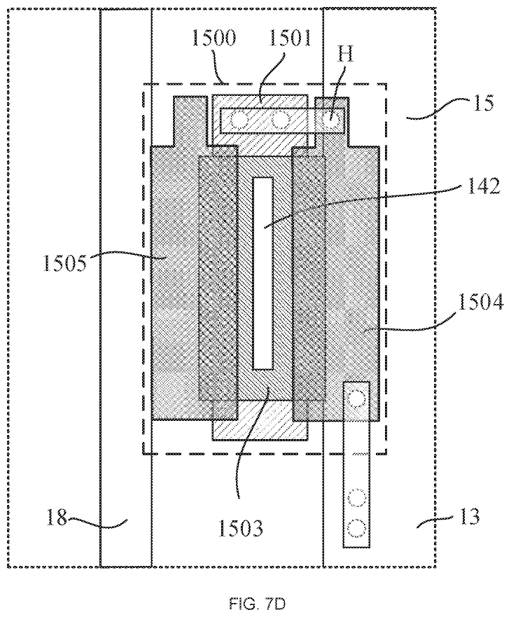

For example, the at least one conductive pattern 13 is directly electrically connected to the common electrode line 18 through at least one wire. In another example, as shown in FIGS. 2A, 3A and 4A, the conductive pattern 13 is electrically connected to the common electrode line 18 through at least one third switch unit 15. Referring to FIGS. 7A to 7D, each third switch unit 15 includes at least one third thin film transistor 1500.

In some embodiments, referring to FIGS. 7C and 7D, the third switch unit 15 includes one third thin film transistor 1500, a second electrode 1505 of the third thin film transistor 1500 is electrically connected to the common electrode line 18, and a first electrode 1504 of the third thin film transistor 1500 is electrically connected to a corresponding conductive pattern 13. In this case, referring to FIG. 7D, a gate 1501 of the third thin film transistor 1500 is electrically connected to the first electrode 1504 thereof; or, referring to FIG. 7C, the gate 1501 of the third thin film transistor 1500 is a floating gate.

In some other embodiments, referring to FIGS. 7A and 7B, the third switch unit 15 includes a plurality of third thin film transistors 1500 that are connected in series. A first electrode 1504 of a third thin film transistor 1500 closet to the conductive pattern 13 is electrically connected to the conductive pattern 13, and a second electrode 1505 of a third thin film transistor 1500 proximate to the common electrode line 18 is electrically connected to the common electrode line 18.

On this basis, for example, referring to FIG. 7A, a gate 1501 of each third thin film transistor 1500 is electrically connected to a first electrode 1504 thereof.

Here, it will be noted that, in a case where the transistors 1500 are connected in series, two adjacent third thin film transistors 1500 may share a same electrode. For example, as shown in FIG. 7A, the third switch unit 15 includes three third thin film transistors 1500, which are a left third thin film transistor 1500, a middle third thin film transistor 1500, and a right third thin film transistor 1500 in a direction from right to left in FIG. 7A. Taking the middle third thin film transistor 1500 as an example, a second electrode of the middle third thin film transistor 1500 is a same electrode as a first electrode of the left third thin film transistor 1500, and a first electrode of the middle third thin film transistor 1500 is a same electrode as a second electrode of the right third thin film transistor 1500.

In another example, referring to FIG. 7B, the gate 1501 of each transistor 1500 is a floating gate (that is, the gate 1501 is not electrically connected to any other portion of the third thin film transistor 1500, or any other component or signal line outside the third thin film transistor 1500).

It will be noted that, in a case where the gate 1501 of each third thin film transistor 1500 included in the third switch unit 15 is the floating gate, the bidirectional transmission of an electrostatic current may be realized. That is, the electrostatic current may flow from the at least one conductive pattern 13 to the common electrode line 18, or from the common electrode line 18 to the at least one conductive pattern 13. On this basis, in a case where a large amount of electrostatic charges are generated on a certain signal line 12, the electrostatic charges on this signal line 12 may be conducted to the common electrode line 18 via a corresponding first switch unit 14 and a corresponding conductive pattern 13, and then the electrostatic charges may be conducted from the common electrode line 18 to other signal lines 12. In this way, it is possible to further increase available for electrostatic charge distribution, and reduce the risks of the accumulation of the electrostatic charges and ESD.

In this way, when there are electrostatic charges on the conductive pattern 13, the third switch unit 15 may be turned on to conduct the electrostatic charges to the common electrode line 18. On the one hand, an area available for electrostatic charge distribution in the display panel 1 may be increased, thereby reducing risks of accumulation of the electrostatic charges and ESD (Electro-Static discharge), and increasing an antistatic capability of the display panel 1, on the other hand, since the common electrode line 18 may be grounded, the static electricity may be led out. A structure of the third switch unit 15 may be adaptively adjusted with reference to a structure of the first switch unit 14.

In some embodiments, in the case where the third switch unit 15 includes the plurality of third thin film transistors 1500 connected in series, and a gate 1503 of a third thin film transistor 1500 closet to the conductive pattern 13 (i.e., the right third thin film transistor 1500) is electrically connected to the conductive pattern 13, a width-to-length channel ratio of the third thin film transistor 1500 closet to the conductive pattern 13 in the third switch unit 15 is less than a width-to-length channel ratio of the third thin film transistor 1500 farther away from the conductive pattern 13.

Here, as shown in FIG. 7A, the width-to-length channel ratio of the third thin film transistor 1500 refers to a ratio of a width W to a length L of a conductive channel in the active layer 1503 of the third thin film transistor 1500. The width-to-length channel ratio of the third thin film transistor 1500 and a drop voltage across the third thin film transistor 1500 are inversely proportional. That is, the greater the width-to-length channel ratio of the third thin film transistor 1500 is, the less the drop voltage across the third thin film transistor 1500 is.

For example, with continued reference to FIG. 7A, a width-to-length channel ratio of the right third thin film transistor 1500 is greater than a width-to-length channel ratio of the middle third thin film transistor 1500 and a width-to-length channel ratio of the left third thin film transistor 1500. In this way, in a case where the electrostatic charges generated on the signal line 12 need to be conducted to the common electrode line 18, a drop voltage across the right third thin film transistor 1500 is less, which may be beneficial to turn on the middle third thin film transistor 1500 and the left third thin film transistor 1500 when there are electrostatic charges that need to be conducted to the common electrode line 18.

In some embodiments, as shown in FIGS. 7A to 7D, the active layers 1503 of each third thin film transistors 1500 in the third switch unit 15 are provided with openings 142.

For example, the opening 142 may be in a shape of a rectangle, and an extending direction of the opening 142 may be substantially perpendicular to an extending direction of a width side of a conductive channel in a corresponding active layer 1503. A width of the opening 142 may be less than a width of an overlapping region of orthographic projections of the active layer 1403 and the gate 1401 on a plane where the active layer 1403 is located, and a length of the opening 142 may be less than a length of the overlapping region.

In some embodiments, the display panel 1 further includes at least one fourth switch unit 16. As shown in FIGS. 3A, 3B, 4A, 4B, 5A and 6A, a signal line 12 that is not electrically connected to a corresponding conductive pattern 13 through the first switch unit 14 is electrically connected to the corresponding conductive pattern 13 through a fourth switch unit 16 and a second switch unit 17.

The following description will be illustratively made by taking an example in which each second signal line 121 is electrically connected to the corresponding conductive pattern 13 through the fourth switch unit 16 and the second switch unit 17 with reference to FIGS. 3A and 3B.

A first end M of the fourth switch unit 16 is electrically connected to the second signal line 121, and a second end N of the fourth switch unit 16 is electrically connected to the corresponding conductive pattern 13. A first end M of the second switch unit 17 is electrically connected to the corresponding conductive pattern 13, and a second end N of the second switch unit 17 is electrically connected to the second signal line 121.

For example, as shown in FIGS. 3A and 3B, the fourth switch unit 16 includes two thin film transistors 1600 connected in series, and a gate of each thin film transistor 1600 is electrically connected to a first electrode thereof. A gate of a thin film transistor 1600 closet to the second signal line 121 is electrically connected to the second signal line 121, and a second electrode of the thin film transistor 1600 closet to the corresponding conductive pattern 13 is electrically connected to the conductive pattern 13.

The second switch unit 17 includes two second thin film transistors 1700 connected in series, and a gate of each second thin film transistor 1700 is electrically connected to a first electrode of the second thin film transistor 1700. A gate of a second thin film transistor 1700 closet to the corresponding conductive pattern 13 is electrically connected to the corresponding conductive pattern 13, and a second electrode of a second thin film transistor 1700 closet to the second signal line 121 is electrically connected to the second signal line 121.

After the electrostatic charges generated on the second signal line 121 are conducted to the corresponding conductive pattern 13 through the fourth switch unit 16, on one hand, since the common electrode line 18 connected to the conductive pattern 13 may be grounded, the electrostatic charges may be conducted out, which is beneficial to reduce the electrostatic voltage in time; on the other hand, in a case where a large amount of electrostatic charges are generated on a certain second signal line 121, the second signal line 121 may conduct the electrostatic charges to a corresponding conductive pattern 13 through a corresponding fourth switch unit 16, and the conductive pattern 13 may conduct part of the electrostatic charges to second signal lines 121 connected to the conductive pattern 13 together with the certain second signal line 121 through the a corresponding second switch units 17, thereby reducing a risk of accumulation of the electrostatic charges.

For example, in a fourth switch unit 16, a width-to-length channel ratio of a thin film transistor 1600 closet to the second signal line 121 is greater than a width-to-length channel ratio of a thin film transistor 1600 closet to the conductive pattern 13.

The above are only specific implementations of the present disclosure, but the protection scope of the present disclosure is not limited thereto. Any person skilled in the art can readily conceive of changes or replacements within the technical scope of the present disclosure, which shall all be included in the protection scope of the present disclosure. Therefore, the protection scope of the present disclosure shall be subject to the protection scope of the claims.

What is claimed is:

1. A display panel, comprising:
a plurality of signal lines, at least one conductive pattern, and a plurality of first switch units; wherein
each of at least part of the signal lines is electrically connected to the at least one conductive pattern through at least one first switch unit; each first switch unit is connected between a corresponding signal line and a corresponding conductive pattern, the first switch unit includes:
a control portion, the control portion being electrically connected between the corresponding signal line and the electrostatic buffer portion, and being configured to close a line between the signal line and the electrostatic buffer portion in response to an electrostatic voltage of electrostatic charges conducted from the corresponding signal line; and
an electrostatic buffer portion, the electrostatic buffer portion including a connecting sub-portion and an extension sub-portion; and the control portion, the corresponding conductive pattern and the extension sub-portion being electrically connected together through the connecting sub-portion.

2. The display panel according to claim 1, wherein the control portion includes a first thin film transistor; a first electrode of the first thin film transistor is electrically connected to the corresponding signal line, and a second electrode of the first thin film transistor is electrically connected to a first end of the connecting sub-portion; and a gate of the first thin film transistor is electrically connected to the first electrode of the first thin film transistor, or the gate of the first thin film transistor is a floating gate;
the first switch unit further includes an insulating layer and a first via hole disposed in the insulating layer, the insulating layer is disposed between the second electrode and the gate of the first thin film transistor; the connecting sub-portion is electrically connected to the corresponding conductive pattern through the first via hole; a second end of the connecting sub-portion is electrically connected to the extension sub-portion.

3. The display panel according to claim 2, wherein the first electrode of the first thin film transistor is electrically connected to the gate of the first thin film transistor; the display panel further comprises a plurality of second switch units,
the corresponding signal line is further electrically connected to the corresponding conductive pattern through one second switch unit; each second switch unit includes:
one second thin film transistor, a gate of the second thin film transistor is electrically connected to a first electrode of the second thin film transistor and the corresponding conductive pattern, and a second electrode of the second thin film transistor is electrically connected to the corresponding signal line; or
a plurality of second thin film transistors connected in series, a gate and a first electrode of each second thin film transistor are electrically connected; a gate and a first electrode of a second thin film transistor closet to the corresponding conductive pattern are electrically connected to the corresponding conductive pattern, and a second electrode of another second thin film transistor closet to the corresponding signal line is electrically connected to the corresponding signal line.

4. The display panel according to claim 2, wherein the gate of the first thin film transistor and the corresponding conductive pattern are disposed in a same layer, and are made of a same material.

5. The display panel according to claim 1, wherein an extending direction of each conductive pattern is substantially perpendicular to an extending direction of a signal line electrically connected thereto; and
the extension sub-portion extends in an extending direction of the corresponding conductive pattern electrically connected thereto.

6. The display panel according to claim 5, wherein a length of the extension sub-portion in an extending direction thereof is greater than or equal to twice a width of the corresponding conductive pattern in a direction perpendicular to the extending direction of the corresponding conductive pattern.

7. The display panel according to claim 5, wherein a length of the extension sub-portion in an extending direction thereof is greater than or equal to twice a width of the extension sub-portion perpendicular to the extending direction thereof.

8. The display panel according to claim 5, wherein an orthographic projection of the extension sub-portion on a plane where the corresponding conductive pattern is located is in a shape of a rectangle.

9. The display panel according to claim 2, wherein the first switch unit further includes at least one groove disposed in the insulating layer the extension sub-portion includes at least one first portion disposed in the at least one groove, and a second portion disposed outside the at least one groove; a plane where a surface of each first portion facing away the corresponding conductive pattern is located is closer to the corresponding conductive pattern than a plane where a surface of the second portion facing away the corresponding conductive pattern is located.

10. The display panel according to claim 2, wherein
the insulating layer includes a first insulating sub-layer and a second insulating sub-layer, and the first insulating sub-layer is disposed on a side of the second insulating sub-layer proximate to the corresponding conductive pattern;
the electrostatic buffer portion further includes at least one buffer pattern disposed between the first insulating sub-layer and the second insulating sub-layer, and the extension sub-portion is electrically connected to the at least one buffer pattern through at least one second via hole disposed in the second insulating sub-layer; and
the buffer pattern is made of a semiconductor material or a conductor.

11. The display panel according to claim 10, wherein the first thin film transistor further includes an active layer disposed between the first insulating sub-layer and the second insulating sub-layer, and the buffer pattern and the active layer are made of a same material.

12. The display panel according to claim 1, comprising at least two conductive patterns, wherein the plurality of signal lines include:
a plurality of gate lines that are electrically connected to one of the at least two conductive patterns; and
a plurality of data lines that are electrically connected to another of the at least two conductive patterns; and
an area of each gate lines is greater than an area of each data line, and an area of an extension sub-portion in a first switch unit electrically connected to the gate line is greater than an area of an extension sub-portion in a first switch unit electrically connected to the data line.

13. The display panel according to claim 1, further comprising a common electrode line, and the at least one conductive pattern being electrically connected to the common electrode line.

14. The display panel according to claim 13, further comprising at least one third switch unit, wherein the at least one conductive pattern is electrically connected to the common electrode line through the at least one third switch unit; each third switch unit includes one third thin film transistor,
a first electrode of the third thin film transistor is electrically connected to the at least one conductive pattern, a second electrode of the third thin film transistor is electrically connected to the common electrode line; a gate and the first electrode of the third thin film transistor are electrically connected, or the gate of the third thin film transistor is a floating electrode.

15. The display panel according to claim 13, further comprising at least one third switch unit, wherein the at least one conductive pattern is electrically connected to the common electrode line through the at least one third switch unit; each third switch unit includes a plurality of third thin film transistors connected in series;
a first electrode of a third thin film transistor closet to the at least one conductive pattern is electrically connected to the at least one conductive pattern, a second electrode of a third thin film transistor closet to the common electrode line is electrically connected to the common electrode line; a gate and the first electrode of each third thin film transistor are electrically connected, or the gate of each third thin film transistor is a floating electrode.

16. The display panel according to claim 15, wherein a width-to-length channel ratio of the third thin film transistor closet to the at least one conductive pattern is greater than a width-to-length channel ratio of a third thin film transistor farther away from the at least one conductive pattern.

17. The display panel according to claim 1, wherein the at least one conductive pattern includes one conductive pattern, and each signal line is electrically connected to the conductive pattern through one first switching unit.

18. The display panel according to claim 1, wherein the at least one conductive pattern includes two conductive patterns that are respectively arranged at two opposite sides of the plurality of signal lines, and the signal line is electrically connected to the two conductive patterns through two first switching units, respectively.

19. A display device, wherein the display device comprises the display panel according to claim 1.
